(19) United States
(12) Patent Application Publication
(10) Pub. No.: US 2019/0294290 A1
(43) Pub. Date: Sep. 26, 2019

(54) DISPLAY SUBSTRATE AND SHORT-CIRCUIT DETECTING METHOD THEREOF, AND DISPLAY DEVICE

(71) Applicants: BOE Technology Group Co., Ltd., Beijing (CN); Chongqing BOE Optoelectronics Technology Co., Ltd., Chongqing (CN)

(72) Inventors: Xun Pu, Beijing (CN); Xin Bi, Beijing (CN); Junhui Wu, Beijing (CN)

(21) Appl. No.: 16/126,011

(22) Filed: Sep. 10, 2018

(30) Foreign Application Priority Data
Mar. 26, 2018 (CN) 201810251602.2

(51) Int. Cl. G06F 3/041; G01R 31/02; G01R 31/28

(52) U.S. Cl. CPC G06F 3/0416; G01R 31/2825; G01R 31/025

(57) ABSTRACT

A display substrate, a short-circuit detecting method, and a display device are provided. The display substrate includes: a plurality of touch control electrodes, a plurality of touch control signal lines, a voltage receiving end, and a plurality of switch circuits. The plurality of touch control electrodes are divided into a plurality of test groups. Each of the touch control electrodes belongs to one of the plurality of test groups. Each of the switch circuits is connected to all touch control electrodes in a test group through the touch control signal line. The switch circuit is configured to switch a connection state between the connected touch control electrodes and the voltage receiving end under the control of the connected switch control signal. Based on the structure of display substrate, it is possible to detect whether there is a short circuit between the touch control electrodes in the electrical test.

This application claims priority to Chinese Patent Application No. 201810251602.2, filed with the State Intellectual Property Office on Mar. 26, 2018 and titled “Display substrate and short-circuit detecting method thereof, and display device”, the entire contents of which are incorporated herein by reference.

### TECHNICAL FIELD

The present disclosure relates to a display substrate and a short-circuit detection method thereof, and a display device.

### BACKGROUND

In an electrical test of a display product, a driving signal can be uniformly provided to all the electrode patterns by using a shorting bar fabricated on a substrate, so that it is possible to detect whether the display product is defective by direct observation. For example, when an electrode pattern cannot receive the driving signal due to a connection lead being disconnected, a display area at the corresponding position cannot be normally displayed. Based on this, it is possible to detect whether or not there is a broken circuit in a circuit structure.

### SUMMARY

There is provided a display substrate and a short-circuit detection method thereof, and a display device in the present disclosure.

In a fist aspect, there is provided a display substrate comprising: a plurality of touch control electrodes in a display area; a plurality of touch control signal lines, each of the touch control signal lines connecting one of the touch control electrodes to a peripheral circuit area of the display substrate; a voltage receiving end in the peripheral circuit area; and a plurality of switch circuits in the peripheral circuit area, each of the switch circuits being connected to the voltage receiving end, and each of the switch circuits being respectively connected with a switch control signal; wherein the plurality of touch control electrodes are divided into a plurality of test groups, and each of the touch control electrodes belongs to one of the plurality of test groups, and each of the switch circuits is connected to all of the touch control electrodes in one of the test groups through the touch control signal line, and the switch circuit is configured to switch a connection state between each of the connected touch control electrodes and the voltage receiving end under the control of the connected switch control signal.

In a possible implementation, the plurality of touch control electrodes are divided into at least two test groups, and any two adjacent touch control electrodes respectively belong to two different test groups of the at least two test groups.

In a possible implementation, the voltage receiving end comprises a plurality of sub-receiving ends, and each of the sub-receiving ends is connected to a switch circuit to provide a received voltage and the switch control signal to the connected switch circuit.

In a possible implementation, the switch circuit comprises at least one transistor, and a first electrode of each of the transistors is connected to a touch control electrode in a corresponding test group, a gate and a second electrode of each of the transistors are connected to a corresponding sub-receiving end, and the first and second electrodes of the transistor are one of a source and a drain of the transistor respectively.

In a possible implementation, there is a fan-out area in the peripheral circuit area, and the plurality of touch control signal lines are connected to the plurality of switch circuits through the fan-out area.

In a possible implementation, a number of the touch control signal lines is the same as a number of the touch control electrodes, and a first end of each of the touch control signal lines is respectively connected to one of the plurality of the touch control electrodes.

In a possible implementation, the switch circuit comprises at least one transistor, and a first electrode of each of the transistors is connected to a touch control electrode in a corresponding test group, a gate of each of the transistors is connected to a corresponding switch control signal, and a second electrode of each of the transistors is connected to the voltage receiving end, and the first and second electrodes of the transistor are one of a source and a drain of the transistor respectively.

In a possible implementation, the display substrate comprises two voltage receiving ends in the peripheral circuit area, and the two voltage receiving ends are respectively on opposite sides of the plurality of switch circuits to provide same electrical signal to each of the switch circuits.

In a possible implementation, a chip area is in the peripheral circuit area, and the plurality of switch circuits are on a side of the chip area adjacent to the display area.

In a second aspect, there is provided a display device comprising any of the above mentioned display substrates.

In a third aspect, there is provided a short-circuit detecting method for a display substrate, comprising: detecting whether there is a short circuit between a first test group and a second test group according to whether there is a touch control electrode receiving the test voltage in the second test group, when all the touch control electrodes in the first test group are connected to the voltage receiving end through the switch control signal and a test voltage is provided to the voltage receiving end, wherein the first test group and the second test group are respectively one of the plurality of test groups.

In a fourth aspect, there is provided a short-circuit detecting method for a display substrate comprising: detecting whether there is a short circuit between a first test group and a second test group according to whether there is a difference between the test voltages received by the first test group and the second test group, when all the touch control electrodes in each of the test groups are connected to a corresponding sub-receiving end through the switch control signal and different test voltages are provided to each of the sub-receiving ends respectively, wherein the first test group and the second test group are respectively one of the plurality of test groups.

### BRIEF DESCRIPTION OF THE DRAWINGS

FIG. 1 is a schematic diagram of a structure of a display substrate according to an embodiment of the present disclosure;

FIG. 2 is a schematic diagram of a circuit structure of a display substrate according to an embodiment of the present disclosure;

FIG. 3 is a schematic diagram of a circuit structure of a display substrate according to another embodiment of the present disclosure;

FIG. 4 is a schematic diagram of a circuit structure of a display substrate according to a comparative embodiment of the present disclosure;

FIG. 5 is a schematic diagram of a circuit structure of a display substrate according to another embodiment of the present disclosure;

FIG. 6 is a schematic diagram of a structure of a display substrate according to another embodiment of the present disclosure; and

FIG. 7 is a schematic diagram of a structure of a display device according to an embodiment of the present disclosure.

### DETAILED DESCRIPTION

The embodiments of this disclosure will be described in details with reference to the enclosed drawings, to clearly present the principles and benefits of the present disclosure. Obviously, the embodiments presented here are merely some rather than all embodiments of the present disclosure. All other embodiments obtained by those skilled in the art based on the embodiments of the present disclosure, without requiring creative works, shall fall within the protect scope of the present disclosure. Unless otherwise defined, technical terms or scientific terms used in the present disclosure should have the ordinary meaning understood by those of ordinary skill in the art. The words “first”, “second” and similar terms used in the present disclosure do not denote any order, quantity, or importance, and are merely used to distinguish different components. The word “comprise” or similar terms mean that elements or objects appearing before the term cover the listed elements or objects and its equivalents appearing after the term, without excluding other elements or objects. The word “connected” or “coupled” and similar terms are not limited to physical or mechanical connections, and may include electrical connection that is direct or indirect.

It can be noted that the conventional test method is insufficient for the detection of whether there is a short circuit in the circuit structure. For example, when a short circuit occurs between an electrode pattern and a similar electrode pattern, the driving signals are still uniformly provided via the shorting bar on the two electrode patterns, which is hardly changed compared to the case where no short circuit occurs, and thus it cannot be detected during the electrical test. It is easy to make the defective product continue to be processed as a good product, resulting in economic loss and waste of production resources.

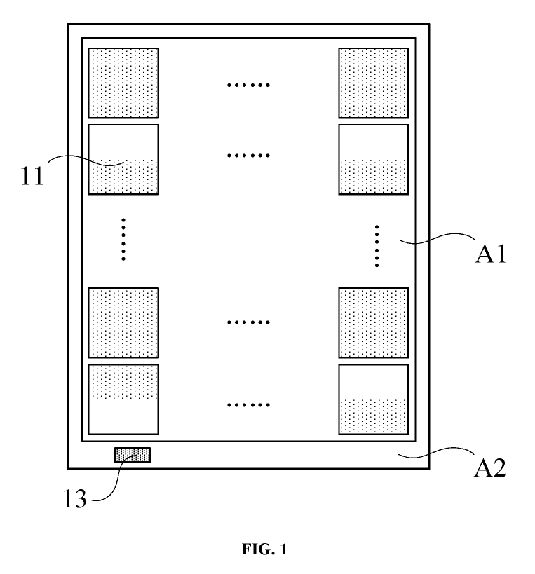

FIG. 1 is a schematic diagram of a structure of a display substrate according to an embodiment of the present disclosure. It should be noted that the display substrate described herein may be, for example, an array substrate, a color film substrate, an organic light-emitting diode display panel, or a touch control panel, and may not be limited thereto. Referring to FIG. 1, the display substrate includes a display area A1 and a peripheral circuit area A2. The display substrate further includes a plurality of touch control electrodes 11 located in the display area A1. Exemplarily, the peripheral circuit area A2 in FIG. 1 surrounds the display area A1. The plurality of touch control electrodes 11 are arranged in a plurality of rows and columns in the display area A1. It should be understood that, within a possible range, the peripheral circuit area A2 may be located on a side of the display area A1, and may also be located on opposite sides of the display area A1; and within a possible range, the plurality of touch control electrodes 11 may be arranged according to any unit arrangement in a plane, for example, arranged in a slanted grid, a triangular grid, a diamond grid, and the like. The display substrate further includes a voltage receiving end 13 in the peripheral circuit area A2. Illustratively, the plurality of touch control electrodes 11 are also used as a common electrode in the display substrate. The voltage receiving end 13 is configured for transmitting a common voltage (VCOM) from the outside of the display substrate to the touch control electrode 11 in the display area A1. For the sake of clarity of the illustration, a plurality of touch control signal lines 12 for connecting the plurality of touch control electrodes 11 from the display area A1 to the peripheral circuit area A2 are not shown in FIG. 1. In the case where each of the touch control electrodes 11 is connected to a corresponding touch control signal line 12, the number of the touch control electrodes 11 is consistent with the number of the touch control signal lines 12.

In an electrical test example in the related art, each of the touch control signal lines 12 is connected to the voltage receiving end 13, and the voltage receiving end 13 is located in a cutting area (an area of the display substrate which is to be cut off). That is, after the test is completed, the voltage receiving end 13 will be cut off from the display substrate. During the test, a full gray scale data voltage is provided to the pixel electrodes of all the sub-pixels of the display area A1, and a common voltage is provided to all the touch control electrodes 11 through the voltage receiving end 13, so as to make the display area A1 display a white monochromatic picture. When any of the touch control signal lines 12 has a broken circuit, the display area where the touch control electrodes 11 connected with touch control signal lines 12 are located cannot present a white monochrome picture normally, so that the broken-circuit detection of the touch control signal line 12 can be performed by observing the picture displayed in the display area where each of the touch control electrodes 11 is located. However, the above test cannot detect a short circuit occurring between different touch control electrodes 11, because whether or not such a short circuit occurs, a common voltage will be applied to each of the touch control electrodes 11, and the test result cannot reflect such a problem.

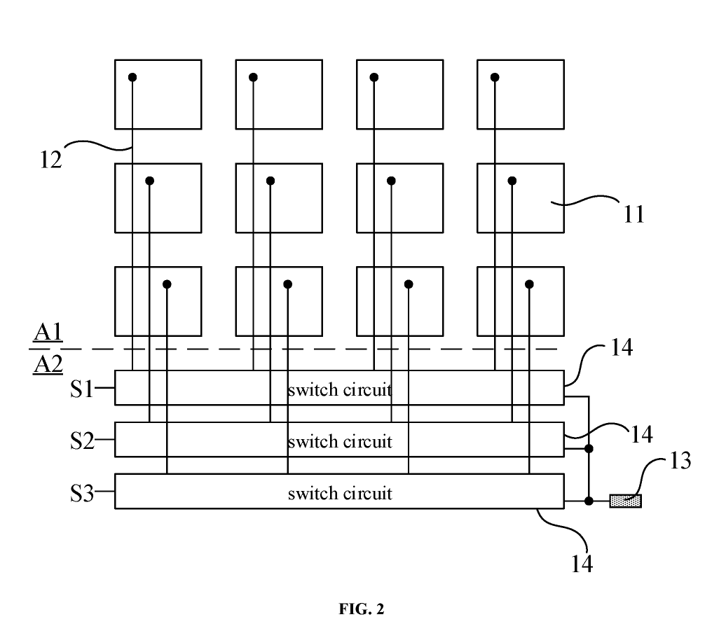

FIG. 2 is a schematic diagram of a circuit structure of a display substrate according to an embodiment of the present disclosure. Referring to FIG. 2, the display substrate in the embodiment of the present disclosure further includes a plurality of switch circuits 14 located in the peripheral circuit area A2. The plurality of switch circuits 14 each are connected to the voltage receiving end 13. Each of the switch circuits 14 is connected to a switch control signal (in FIG. 2, three switch circuits 14 being respectively connected to switching signals S1/S2/S3 is taken as an example). In addition, the plurality of touch control electrodes 11 are divided into a plurality of test groups. Each of the touch control electrodes 11 belongs to one of the plurality of test groups. Each of the switch circuits 14 is connected to all of the touch control electrodes 11 in a test group through the touch control signal line 12. The switch circuit 14 is configured to switch a connection state (for example, switch between a “connected state” and a “disconnected state”) between each of the connected touch control electrodes 11 and the voltage receiving end 13 under the control of the connected switch control signal.

Taking FIG. 2 as an example, the touch control electrodes 11 arranged in three rows and four columns are divided into three test groups according to the row. The first row (hereinafter referred to as a first test group) of touch control electrodes 11 from top to bottom is connected to the switch circuit 14 connected to the switch signal S1 through the touch control signal line 12. The second row (hereinafter referred to as a second test group) of touch control electrode 11 is connected to the switch circuit 14 connected to the switch signal S2 through the touch control signal line 12. The third row (hereinafter referred to as a third test group) of touch control electrodes 11 is connected to the switch circuit 14 which is connected the switch signal S3 through the touch control signal line 12. In this way, the electrical connection between each test group and the voltage receiving end 13 can be individually controlled by the switch control signals S1/S2/S3. For example, the switch control signals S1 and S2 can be set to an active level and the switch control signal S3 can be set to an inactive level, such that the touch control electrodes 11 of the first and second test groups are electrically connected to the voltage receiving end 13 and the touch control electrodes 11 of the third test group are not electrically connected to the voltage receiving end 13.

In an electrical test example, the electrical test is performed one by one among a plurality of test groups. For example, the voltage receiving end 13 first provides a common voltage to the first row of touch control electrodes 11 through the switch control signal S1, and simultaneously provides a full gray scale data voltage to the pixel electrodes of all the sub-pixels of the display area A1, so that the display area corresponding to the first row of touch control electrodes 11 presents a white monochrome picture. Then, while keeping the data voltage unchanged, the voltage receiving end 13 provides a common voltage to the second row of touch control electrodes 11 through the switch control signal S2, so that the display area corresponding to the second row of touch control electrodes 11 presents a white monochrome image, and so on. Thus, if there is a short circuit between the first row of touch control electrodes 11 and the second row of touch control electrodes 11, a white monochrome image will be presented in a display area corresponding to the short-circuited touch control electrodes 11 in the second row when the first test group is under test. When this phenomenon is observed, it can be determined that there is a short circuit between the touch control electrode 11 corresponding to the display area and the first row of touch control electrodes 11. Therefore, the short circuit existing between any two test groups can be detected via this test. That is, whether there is a short circuit between the touch control electrodes is detected in the electrical test.

It should be understood that, the test method, in which the above-mentioned touch control electrode 11 is used as a common electrode and the display picture is observed when a full gray scale data voltage and a common voltage are provided, is merely an example of an electrical test method. According to the function of the touch control electrode 11, the electrical test method can also be detecting the electromagnetic shielding effect of the touch control electrode when a stable voltage is provided, or detecting a signal received on an opposite electrode of the touch control electrode when an analog touch control signal is provided, which is not limited thereto.

It can be seen that, it is can be performed in the embodiments of the present disclosure a separate circuit test for each test group based on the connection relationship between the plurality of switch circuits and the plurality of test groups, so that a short circuit occurring between the test groups can be reflected in the test results. Based on this, it is possible to realize the detection of a short circuit in the circuit structure in the electrical test, which helps the short-circuit defect to be detected in time and improves the production efficiency.

In an example, a short-circuit detecting method for a display substrate may include:

when all the touch control electrodes in the first test group are connected to the voltage receiving ends through the switch control signal and a test voltage is provided to the voltage receiving end, whether there is a short circuit between the first test group and the second test group is detected according to whether there is a touch control electrode that receives the test voltage in the second test group; wherein the first test group and the second test group respectively is one of the plurality of test groups.

It can be understood that an exemplary implementation of the above short-circuit detecting method is included in the above electrical test example. In the exemplary implementation, the test voltage provided to the voltage receiving end is a constant common voltage, the test performed is a lighting test of the display area corresponding to a target test group, and the obtained test result includes the display condition in the display area. If a lit-up area appears in the display area corresponding to any test group when the test is not performed, it indicates that a short circuit has occurred between the test group and the target test group, so that each test group can be sequentially tested to determine the short circuit condition between any two test groups. According to the above description, the specific implementations of other electrical test methods can be obtained analogously, which will not be described herein.

It should be understood that any of the display substrates involved in the present disclosure can use the short-circuit detecting method as described above to perform detection of whether a short circuit occurs between test groups. That is, whether or not there is a short circuit can be realized in the electrical test, which can help the timely detection of short-circuit defects and improve production efficiency.

It should be noted that the voltage receiving end in the present disclosure refers to a conductor structure that provides a test voltage to the touch control electrode during the electrical test. The method of providing the test voltage from the outside of the display panel to the voltage receiving end may include, but is not limited to, the probe being electrically connected to the spacer, the plug being electrically connected to the socket, and the conductive clip being electrically connected to the spacer. It should also be noted that the switch control signal in the present disclosure may be generated outside the display substrate and transmitted to the switch circuit through the conductor structure on the display substrate, or may be generated through the on/off of a mechanical switch on the display substrate and transmitted to the switch circuit, or may also be generated by a controller on the display substrate through external communication and transmitted to the switch circuit, which is not limited thereto.

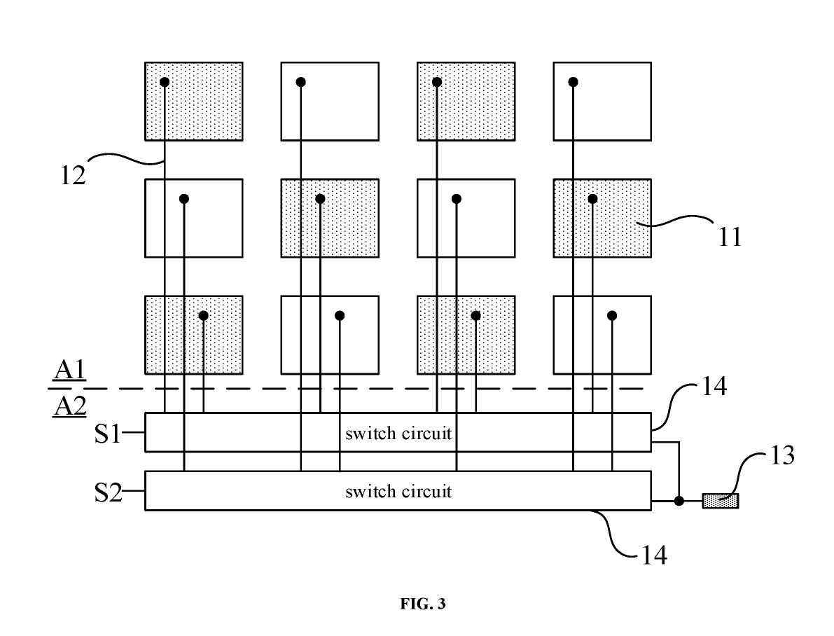

FIG. 3 is a schematic diagram of a circuit structure of a display substrate according to another embodiment of the present disclosure. Referring to FIG. 3, in the embodiments of the present disclosure, the plurality of touch control electrodes 11 are divided into two test groups. Any two adjacent touch control electrodes 11 respectively belongs to one of the two test groups. For the sake of clarity, all of the touch control electrodes 11 of one of the test groups are identified by shading in FIG. 3. By comparing FIG. 2 and FIG. 3, it can be seen that unlike the division manner shown in FIG. 2 that is based on the row, a test group division manner in the embodiments takes a division manner similar to a black and white checkerboard as an example to illustrate an implementation in which any two adjacent touch control electrodes 11 mentioned above respectively belongs to one of the two test groups. Thus, when a short circuit occurs between any one of the touch control electrodes 11 and the adjacent touch control electrodes 11 thereto, the test result can reflect the problem (for example, when a test is performed according to the example of the above electrical test method, the phenomenon showing short circuit is: a bright cross centering on a touch control electrode 11 appears). Moreover, only two switch control signals and two switch circuits can be used in the embodiments. That is, the required circuit configuration is simpler. It can be seen that the embodiments of the present disclosure can realize the detection of the short circuit condition between any two adjacent touch control electrodes 11 by using only two switch control signals and two switch circuits, thereby realizing the simpler and comprehensive short circuit detection between the touch control electrodes, which is more conducive to the improvement of production efficiency. It should be understood that the plurality of touch control electrodes 11 may be divided into three or more test groups, and any two adjacent touch control electrodes 11 respectively belong to two different tests in the test groups. In this way, the detection of the short circuit condition between any two adjacent touch control electrodes 11 can also be realized.

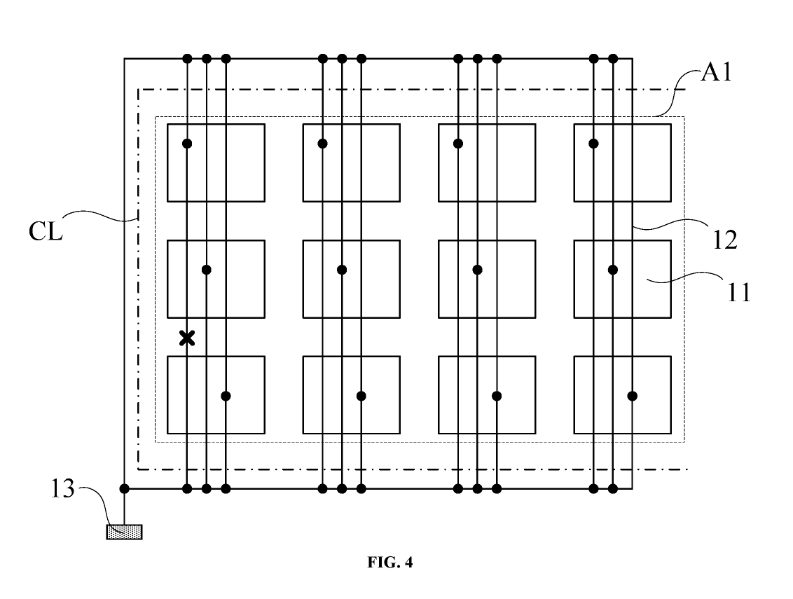

FIG. 4 is a schematic diagram of a circuit structure of a display substrate according to a comparative example of the present disclosure. Referring to FIG. 4, in the comparative example, the plurality of touch control signal lines 12 are conductor lines whose both ends are located outside the display area A1 and the plurality of touch control signal lines 12 are shorted to the voltage receiving end 13 outside a cutting line CL. As such, the broken-circuit detection can be performed in the structure shown in this comparative example according to the electrical test example in the related art mentioned above, but a missed detection may occur. For example, if the broken circuit occurs at the position marked with “x” in FIG. 4, the touch control electrode 11 in the upper left corner may still be electrically connected to the voltage receiving end 13 from above by bypassing the path in which the broken circuit occurs. Therefore, the broken circuit problem cannot be reflected in the test result. However, after the structure outside the cutting line CL is cut off from the display substrate, the broken circuit here may affect the connection between the touch control electrode 11 in the upper left corner and the circuit structure outside the display area A1. That is, a broken circuit defect that was not detected in the test appears.

From the comparison of the embodiments of the present disclosure and the above comparative example, it can be seen that since the number of touch control signal lines is the same as the number of touch control electrodes (one-to-one correspondence) and a first end (the upper end in FIG. 2 and FIG. 3) of each touch control signal line 12 is connected to one of the plurality of touch control electrodes 11, two conductive paths between the touch control electrodes 11 and the voltage receiving end 13 will not occur at the same time during the test, thus it will not cause the above-mentioned missed detection.

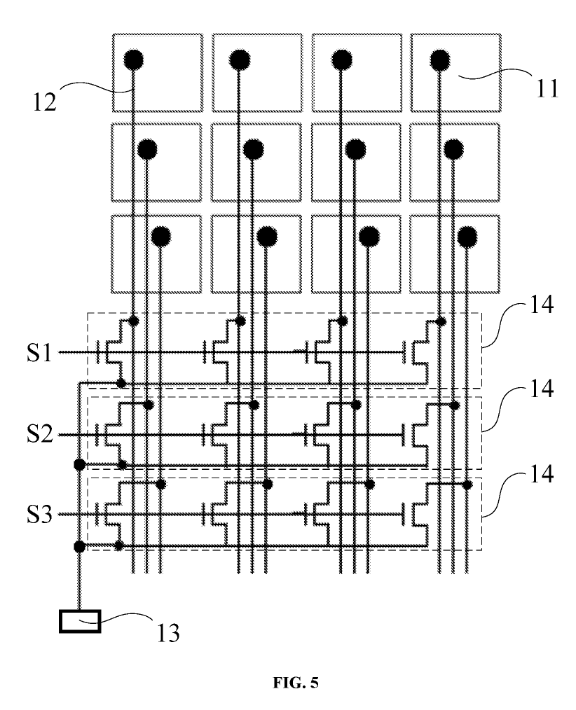

FIG. 5 is a schematic diagram of a circuit structure of a display substrate according to another embodiment of the present disclosure. From the comparison of FIG. 2 and FIG. 5, it can be known that there is provided an exemplary implementation of a switch circuit in the embodiments of the present disclosure. Referring to FIG. 5, the switch circuit 14 in the embodiments of the present disclosure includes at least one transistor (for example, there are four transistors in FIG. 5, and the number of transistors mainly depends on the number of touch control electrodes 11 in the test group). A gate of each transistor is connected to corresponding switch control signals S1/S2/S3. A first electrode of each transistor is connected to the touch control electrode 11 in the corresponding test group. A second electrode of each transistor is connected to the voltage receiving end 13. Herein, the first electrode and the second electrode of the transistor are respectively one of a source and a drain of the transistor. It should be noted that, depending on the specific type of the transistor, the connection relationships of the source and the drain may be respectively set to match the direction of the current flowing through the transistor. When the transistor has a symmetrical structure of the source and the drain, the source and drain can be regarded as two electrodes that are not particularly distinguished.

In an example, when the switch control signal Si is at an active level, the gate and the transistor connected thereto are both in an ON state, so that the first row of touch control electrodes 11 are electrically connected to the voltage receiving end 13. At this time, the switch control signals S2 and S3 are at an inactive level, so that the remaining transistors in FIG. 5 are in an OFF state, and the touch control electrodes 11 in the second and third rows are not electrically connected to the voltage receiving end 13. In order to avoid the accidental turn-on of the transistor in the switch circuit 14 to generate a noise signal, P-type transistors that keep in an OFF state can be employed when the gate is suspending. At this time, the active level of the switch control signal is low level (the inactive level is high level, and the specific range can be determined according to the needs).

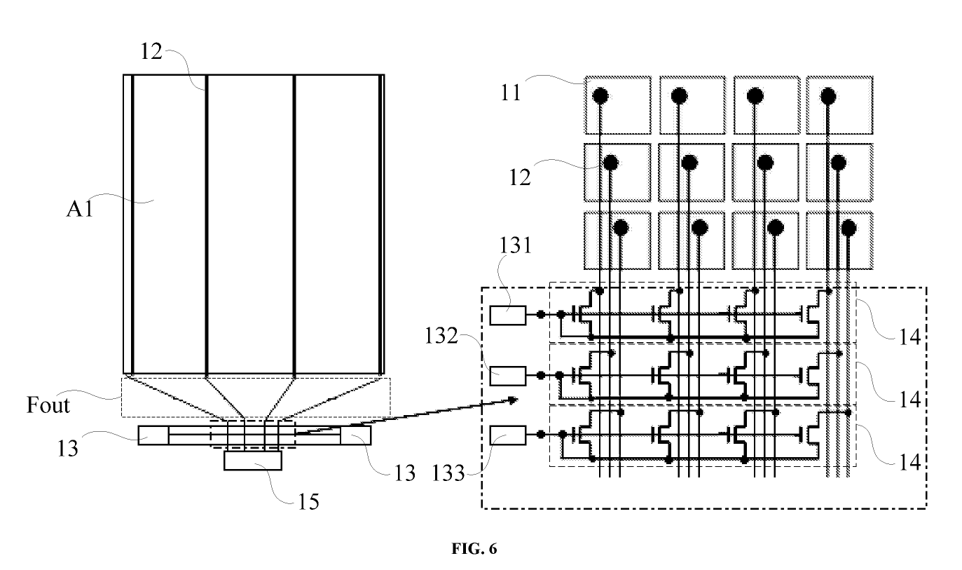

FIG. 6 is a schematic diagram of a structure of a display substrate according to another embodiment of the present disclosure. It can be seen that the embodiment of the present disclosure provides an exemplary implementation of yet another switch circuit. Referring to FIG. 6, in the embodiments of the present disclosure, the voltage receiving end 13 includes a plurality of sub-receiving ends (three sub-receiving ends 131/132/133 in FIG. 6 are taken as an example). Each sub-receiving end is respectively connected to a switch circuit 14 to provide the received voltage and the switch control signal to the switch circuit 14 connected thereto. Herein, the switch circuit 14 includes at least one transistor (four transistors in FIG. 5 being taken as an example, the number of transistors mainly depends on the number of touch control electrodes 11 in the test group). A first electrode of each transistor is connected to one touch control electrode 11 in the corresponding test group. A gate and a second electrode of each transistor are both connected to the corresponding sub-receiving ends 131/132/133. It should be understood that the transistor in the example needs to use a transistor that is in an ON state when a test voltage is provided to the gate. For example, in the case where the test voltage is a common voltage, the transistor needs to adopt a P-type transistor that is in an ON state when a common voltage is on the gate. It can be seen that the switch control signal connected to each switch circuit 14 in the example is provided by the voltage receiving end 13, so that an electrical signal that needs to be externally provided to the display substrate can be omitted, and a corresponding conductor structure on the display substrate for transmitting the electrical signal can be saved. It should also be understood that the implementation of the above-mentioned switch circuit 14 is only an example. The functions of the above-mentioned switch circuit may be realized in other manners with reference to the above structure, which is not limited to the above examples.

In an example, a short-circuit detecting method for a display substrate as shown in FIG. 6 may include:

when all the touch control electrodes in each of the test groups are connected to the corresponding sub-receiving ends through the switch control signal and a different test voltage is respectively provided to each of the sub-receiving ends, whether there is a short circuit is detected between the first test group and the second test group according to whether there is a difference between the test voltages received by the first test group and the second test group; wherein the first test group and the second test group are respectively one of the plurality of test groups.

In the example, an electrical test can be performed simultaneously among a plurality of test groups. In an exemplary implementation, a common voltage corresponding to a different gray scale value is provided to each of the switch circuits 14 through the sub-receiving ends 131/132/133, such that the display area corresponding to the first row of touch control electrodes 11 in the display area A1 presents a white color with an intermediate brightness, the display area corresponding to the second row of touch control electrodes 11 in the display area A1 presents a white color with the highest brightness, and the display area corresponding to the third row of touch control electrodes 11 in the display area A1 presents a white color with the lowest brightness. At this time, if there is a short circuit between the first row of touch control electrodes 11 and the second row of touch control electrodes 11, the display area corresponding to the two rows of touch control electrodes 11 will present a white color with almost the same brightness. When this phenomena is observed, it is determined that there is a short circuit between the touch control electrode 11 corresponding to the display area and the first row of touch control electrodes 11. By analogy, the short circuit existing between any two test groups can be detected by using the above method. That is, whether there is a short circuit between the touch control electrodes is detected in the electrical test.

It can be understood that, in the above exemplary implementations, the test voltage provided to the voltage receiving end is a common voltage corresponding to a different gray scale value, the test performed is a lighting test of the display area corresponding to a target test group, and the obtained test result includes the display condition in the display area. If the difference in brightness between any test group and the target test group is too small, it indicates a short circuit occurs between the test group and the target test group, thus each test group can be sequentially detected to determine the short circuit condition between any two test groups. According to the above description, the specific implementations of other electrical test methods can be obtained analogously, which is not described herein.

It should be understood that as long as the voltage receiving end in the display substrate includes a plurality of sub-receiving ends, any type of display substrate involved in the present disclosure can perform the short-circuit detecting method as described above to detect whether there is a short circuit between the test groups. That is, it is possible to detect whether there is a short circuit in the electrical test, which helps the short-circuit defect to be detected in time and improves the production efficiency.

It can be seen that the design of some other aspects of the peripheral circuit area of the display substrate is also shown in FIG. 6. Referring to FIG. 6, the display substrate in the example includes two voltage receiving ends 13 located in the peripheral circuit area. The two voltage receiving ends 13 are respectively located on opposite sides of the plurality of switch circuits 14 (left and right sides in FIG. 6) to provide the same electrical signal to each of the switch circuits 14. It should be understood that the right part of FIG. 6 omits the other group of three sub-receiving ends set opposite to the three sub-receiving ends 131/132/133. The sub-receiving ends at the left and right sides of each switch circuit 14 during the test are respectively connected to the same test voltage, which makes the test voltage connected to the switch circuit more stable. Of course, the design of the two voltage receiving ends on the opposite sides is not limited to the structure of the switch circuit shown in FIG. 6, and the design can also be applied to FIGS. 2, 3, and 5, for example.

Referring to FIG. 6, in the example, there is a chip area 15 in the peripheral circuit area (which may be an area on the display substrate for attaching the chip, or an area located on the circuit board at the edge of the display substrate for attaching the chip). The plurality of switch circuits 14 are all located on a side of the chip area 15 close to the display area A1. Taking this as an example, this example gives a test circuit structure that does not need to be removed after the test. That is, the chip may not be attached in the chip area 15 during the test. The process including attaching the chip can be performed after the test so as to complete the production of the product. There is no need to remove the circuit structure including the voltage receiving end 13 and the switch circuit 14. It is possible to continue to use this part of the circuit structure for testing in the subsequent use and maintenance process.

In addition, referring to FIG. 6, there is also a fan-out area Fout in the peripheral circuit area in the example. The plurality of touch control signal lines 12 are connected to the plurality of switch circuits 14 via the fan-out area Fout. In this way, if the touch control signal line 12 in the fan-out area Fout is broken, it can be detected in the test. Compared with the electrical test method that cannot detect the broken circuit of the fan-out area, the scope that can be detected in this example is more comprehensive, which is more conducive to the improvement of product production efficiency.

As an example of a material selection method, the conductive material used by the touch control signal line 12 and the voltage receiving end 13 may include, for example, a metal material including at least one element of iron, copper, aluminum, molybdenum, nickel, titanium, silver, zinc, tin, lead, chromium, and manganese, and the components may be set according to application requirements. The touch control electrode 11 may be formed of a transparent conductive material including at least one of indium tin oxide ITO, graphene, a metal mesh, a conductive polymer, and a nano conductive material, and may also be formed by a translucent conductive material such as a silver thin film. The semiconductor material used in the active region of the above transistor may include amorphous silicon, polycrystalline silicon, single crystal silicon, metal oxide semiconductor, or the like, and at least a portion of the region may be doped in accordance with the characteristics of the thin film transistor to be realized. Each of the above structures may be formed by pattern design in the existing film layer. For example, the plurality of touch control signal lines may be formed together with the source electrode and the drain electrode of the transistor in the patterning process of the source/drain conductive layer, which is not limited herein.

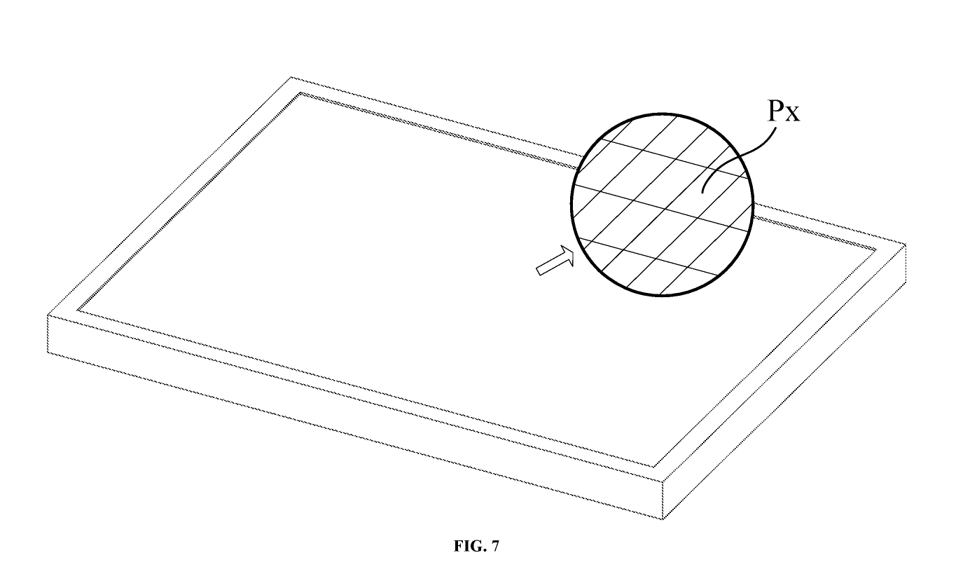

Based on the same disclosure concept, there is provided a display device in the embodiments of the present disclosure. The display device includes any one of the above display substrates. The display device in the embodiments of the present disclosure may be any product or part with a display function, such as a display panel, a mobile phone, a tablet, a TV, a display, a laptop, a digital photo frame, a navigator, and etc. As an example, FIG. 7 shows a schematic diagram of a structure of a display device according to an embodiment of the present disclosure. The display device includes any one of the above display substrates. The display area of the display substrate includes sub-pixel regions Px arranged in rows and columns. The embodiments of the present disclosure can perform a separate circuit test for each test group based on the connection relationship between the plurality of switch circuits and the plurality of test groups, so that a short circuit occurring between the test groups can be reflected in the test results. Based on this, it is possible to realize the detection of a short circuit in the circuit structure in the electrical test, which helps the short-circuit defect to be detected in time and improves the production efficiency.

It should be noted that, for the sake of clarity, only the structures for explaining the technical solution are shown in the drawings of the present disclosure; in the actual product, it is also possible to add, delete or deform within a possible scope on the basis of the drawings of the present disclosure, without affecting the implementation of the technical solution. The above descriptions are merely exemplary embodiments of the present disclosure, and are not intended to limit the present disclosure. Any modifications, equivalents, improvements, etc., within the spirit and principle of the present disclosure, shall fall into the protection scope defined by the appended claims of the present disclosure.

What is claimed is:

1. A display substrate comprising:
a plurality of touch control electrodes in a display area;
a plurality of touch control signal lines, each of the touch control signal lines connecting one of the touch control electrodes to a peripheral circuit area of the display substrate;
a voltage receiving end in the peripheral circuit area; and
a plurality of switch circuits in the peripheral circuit area, each of the switch circuits being connected to the voltage receiving end, and each of the switch circuits being respectively connected with a switch control signal;
wherein the plurality of touch control electrodes are divided into a plurality of test groups, and each of the touch control electrodes belongs to one of the plurality of test groups, and
each of the switch circuits is connected to all of the touch control electrodes in one of the test groups through the touch control signal line, and the switch circuit is configured to switch a connection state between each of the connected touch control electrodes and the voltage receiving end under the control of the connected switch control signal.

2. The display substrate according to claim 1, wherein the plurality of touch control electrodes are divided into at least two test groups, and any two adjacent touch control electrodes respectively belong to two different test groups of the at least two test groups.

3. The display substrate according to claim 1, wherein the voltage receiving end comprises a plurality of sub-receiving ends, and
each of the sub-receiving ends is connected to a switch circuit to provide a received voltage and the switch control signal to the connected switch circuit.

4. The display substrate according to claim 3, wherein the switch circuit comprises at least one transistor, and a first electrode of each of the transistors is connected to a touch control electrode in a corresponding test group,
a gate and a second electrode of each of the transistors are connected to a corresponding sub-receiving end, and
the first and second electrodes of the transistor are one of a source and a drain of the transistor respectively.

5. The display substrate according to claim 1, wherein there is a fan-out area in the peripheral circuit area, and the plurality of touch control signal lines are connected to the plurality of switch circuits through the fan-out area.

6. The display substrate according to claim 1, wherein a number of the touch control signal lines is the same as a number of the touch control electrodes, and a first end of each of the touch control signal lines is respectively connected to one of the plurality of the touch control electrodes.

7. The display substrate according to claim 1, wherein the switch circuit comprises at least one transistor, and a first electrode of each of the transistors is connected to a touch control electrode in a corresponding test group,
a gate of each of the transistors is connected to a corresponding switch control signal, and a second electrode of each of the transistors is connected to the voltage receiving end, and
the first and second electrodes of the transistor are one of a source and a drain of the transistor respectively.

8. The display substrate according to claim 1, wherein the display substrate comprises two voltage receiving ends in the peripheral circuit area, and
the two voltage receiving ends are respectively on opposite sides of the plurality of switch circuits to provide same electrical signal to each of the switch circuits.

9. The display substrate according to claim 1, wherein a chip area is in the peripheral circuit area, and the plurality of switch circuits are on a side of the chip area adjacent to the display area.

10. A display device comprising a display substrate, the display substrate comprising:
a plurality of touch control electrodes in a display area;
a plurality of touch control signal lines, each of the touch control signal lines connecting one of the touch control electrodes to a peripheral circuit area of the display substrate;
a voltage receiving end located in the peripheral circuit area; and
a plurality of switch circuits located in the peripheral circuit area, each of the switch circuits being connected to the voltage receiving end, and each of the switch circuits being respectively connected with a switch control signal;
wherein the plurality of touch control electrodes are divided into a plurality of test groups, and each of the touch control electrodes belongs to one of the plurality of test groups, and
each of the switch circuits is connected to all of the touch control electrodes in one of the test groups through the touch control signal line, and the switch circuit is configured to: switch a connection state between each of the connected touch control electrodes and the voltage receiving end under the control of the connected switch control signal.

11. The display device according to claim 10, wherein the plurality of touch control electrodes are divided into at least two test groups, and any two adjacent touch control electrodes respectively belong to two different test groups of the at least two test groups.

12. The display device according to claim 10, wherein the voltage receiving end comprises a plurality of sub-receiving ends, and
each of the sub-receiving ends is connected to a switch circuit to provide a received voltage and the switch control signal to the connected switch circuit.

13. The display device according to claim 12, wherein the switch circuit comprises at least one transistor, and a first electrode of each of the transistors is connected to a touch control electrode in a corresponding test group,
a gate and a second electrode of each of the transistors are connected to a corresponding sub-receiving end, and
the first and second electrodes of the transistor are one of a source and a drain of the transistor respectively.

14. The display device according to claim 10, wherein there is a fan-out area in the peripheral circuit area, and the plurality of touch control signal lines are connected to the plurality of switch circuits through the fan-out area.

15. The display device according to claim 10, wherein a number of the touch control signal lines is the same as a number of the touch control electrodes, and a first end of each of the touch control signal lines is respectively connected to the plurality of touch control electrodes.

16. The display device according to claim 10, wherein the switch circuit comprises at least one transistor, and a first electrode of each of the transistors is connected to a touch control electrode of a corresponding test group,
a gate of each of the transistors is connected to a corresponding switch control signal, and a second electrode of each of the transistors is connected to the voltage receiving end, and
the first and second electrodes of the transistor are one of a source and a drain of the transistor respectively.

17. The display device according to claim 10, wherein the display substrate comprises two voltage receiving ends in the peripheral circuit area, and
the two voltage receiving ends are respectively on opposite sides of the plurality of switch circuits to provide same electrical signal to each of the switch circuits.

18. The display device according to claim 10, wherein a chip area is in the peripheral circuit area, and the plurality of switch circuits are on a side of the chip area adjacent to the display region.

19. A short-circuit detecting method for a display substrate according to claim 1, comprising:
detecting whether there is a short circuit between a first test group and a second test group according to whether there is a touch control electrode receiving the test voltage in the second test group, when all the touch control electrodes in the first test group are connected to the voltage receiving end through the switch control signal and a test voltage is provided to the voltage receiving end,
wherein the first test group and the second test group are respectively one of the plurality of test groups.

20. A short-circuit detecting method for a display substrate according to claim 3, comprising:
detecting whether there is a short circuit between a first test group and a second test group according to whether there is a difference between the test voltages received by the first test group and the second test group, when all the touch control electrodes in each of the test groups are connected to a corresponding sub-receiving end through the switch control signal and different test voltages are provided to each of the sub-receiving ends respectively,
wherein the first test group and the second test group are respectively one of the plurality of test groups.
